(19) United States
(12) Patent Application Publication
(10) Pub. No.: US 2009/0055699 A1
(43) Pub. Date: Feb. 26, 2009

(54) SEMICONDUCTOR TEST APPARATUS

(75) Inventor: Kazuhiko Murata, Musashino-shi (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION, Tokyo (JP)

(21) Appl. No.: 12/185,454

(22) Filed: Aug. 4, 2008

(30) Foreign Application Priority Data
Aug. 24, 2007 (JP) 2007-218292

(51) Int. Cl. G01R 31/3183; G06F 11/263

(52) U.S. Cl. 714/744; 714/E11.177

(57) ABSTRACT

To provide a semiconductor test apparatus which is capable of adjusting skew efficiently with sufficient operational convenience. The semiconductor test apparatus tests a semiconductor device based on a signal obtained by applying a test signal to the semiconductor device, and includes a driver pin block. The driver pin block is provided with: a plurality of drivers which generate the test signal; at least one adjustment comparator which is connected to output terminals of the drivers and which is used for adjusting timings of the drivers; and a reference signal input terminal to which a reference signal for adjusting a timing of the adjustment comparator is input.

### BACKGROUND OF THE INVENTION

1. Field of the Invention

The present invention relates to a semiconductor test apparatus which tests a semiconductor device such as a semiconductor logic circuit and a semiconductor memory.

Priority is claimed on Japanese Patent Application No. 2007-218292, filed Aug. 24, 2007, the content of which is incorporated herein by reference.

2. Description of Related Art

In general, semiconductor devices include a plurality of types of pins provided for different functions. For example, semiconductor memories have input pins (address pins) to which an address is input, input/output pins (data pins) through which data is input and output, power supply pins, and other control pins. Therefore, semiconductor test apparatuses which test semiconductor devices also have a plurality of types of pins provided for different functions so as to conform to the types of pins of the semiconductor devices. For instance, semiconductor test apparatuses (memory testers) which test semiconductor memories are provided with various pins such as driver pins at which drivers that apply an address to address pins of the semiconductor memories are provided, and I/O (Input/Output) pins at which drivers that apply data to data pins of the semiconductor memories and comparators that receive data output from the data pins are provided.

If there are variations in characteristics between the drivers provided at the driver pins or between the drivers provided at the I/O pins, differences (driver skews) are produced between the timings of signals output from the respective drivers. Similarly, if there are variations in characteristics between the comparators provided at the I/O pins, differences (comparator skews) are produced between the judgment timings when a pass or a fail of a semiconductor device is judged. Since there is a possibility that such skews cause a false test result of a semiconductor device, it is necessary to adjust skew with a high level of accuracy prior to testing the semiconductor device. Japanese Unexamined Patent Application, First Publication No. 2001-228214 (hereinafter referred to as “Patent Document 1”) discloses the technique of adjusting skew using a jig (a short-circuiting chip) which electrically short-circuits a driver pin and an I/O pin.

In recent years, there are increasing demands for reducing costs which are required to test semiconductor devices. In particular, since prices of semiconductor memories are becoming cheaper, it is necessary to perform tests as efficiently as possible. However, the technique disclosed in the Patent Document 1 requires preparatory work in which an operator manually carries a jig onto a test head and locates the jig. Therefore, a problem arises in that operations are extremely inconvenient and are quite inefficient.

In other words, since the adjustment of skew is such that differences in timing between drivers provided in a semiconductor test apparatus are adjusted or differences in timing between comparators provided in a semiconductor test apparatus are adjusted, taking the operational convenience into consideration, it is desirable that skew be adjusted by simply giving an instruction from an operator without preparing an extra jig. Moreover, while work for preparing a jig requires several tens of minutes, the adjustment of skew normally requires several tens of minutes. That is to say, since a time comparable to the time which is necessary to adjust skew is required for preparatory work alone, it is extremely inefficient.

### SUMMARY OF THE INVENTION

The present invention has been made in view of the foregoing circumstances, and an object of the present invention is to provide a semiconductor test apparatus which is capable of adjusting skew efficiently with sufficient operational convenience.

In order to solve the foregoing problems, a semiconductor test apparatus of the present invention tests a semiconductor device based on a signal obtained by applying a test signal to the semiconductor device, and includes a driver pin block, the driver pin block including: a plurality of drivers which generate the test signal; at least one adjustment comparator which is connected to output terminals of the drivers and which is used for adjusting timings of the drivers; and a reference signal input terminal to which a reference signal for adjusting a timing of the adjustment comparator is input.

In accordance with the present invention, the timing of the adjustment comparator is adjusted using the reference signal input from the reference signal input terminal, and the timings of the plurality of the drivers are adjusted using the adjustment comparator whose timing has been adjusted.

Preferably, the semiconductor test apparatus further includes: a reference signal generation unit which generates the reference signal; and a control unit which adjusts the timing of the adjustment comparator by controlling the reference signal generation unit to supply the reference signal to the driver pin block through the reference signal input terminal, and adjusts the timings of the drivers in accordance with a signal output from the adjustment comparator.

Preferably, the control unit adjusts the timings of the adjustment comparator and the drivers with the output terminals of the drivers opened.

Preferably, the driver pin block includes a switch unit which connects one of the drivers and the reference signal input terminal to the adjustment comparator.

Preferably, the adjustment comparator includes: a plurality of first comparators respectively connected to the output terminals of the drivers; and a second comparator connected to the reference signal input terminal, and the semiconductor test apparatus further includes a selection unit which selects one of outputs of the first comparators and an output of the second comparator.

Preferably, the semiconductor test apparatus further includes a judgment unit which judges a pass or a fail of the semiconductor device at a judgment timing based on an expected value and the signal output from the adjustment comparator, and the control unit adjusts the timing of the adjustment comparator by determining a turning point between the pass and the fail based on a judgment result of the judgment unit while varying the judgment timing and setting the judgment timing to a timing for which the turning point has been determined.

Preferably, the semiconductor test apparatus further includes a judgment unit which judges a pass or a fail of the semiconductor device based on an expected value and the signal output from the adjustment comparator, and the control unit adjusts the timing of a driver by determining a turning point between the pass and the fail based on a judgment result of the judgment unit while varying a timing of a signal supplied to an input terminal of the driver and setting the timing of the signal supplied to the input terminal of the driver to a timing for which the turning point has been determined.

Preferably, the first comparators and the second comparator are manufactured and integrated by the same manufacturing process.

In accordance with the present invention, the timing of the adjustment comparator is adjusted using the reference signal input from the reference signal input terminal, and the timings of the plurality of the drivers are adjusted using the adjustment comparator the timing of which has been adjusted. As a result, the timings of the drivers can be adjusted without using a jig (a short-circuiting chip) which is required in conventional semiconductor test apparatuses. As a result, the operational convenience can be increased, and skew can be adjusted efficiently without requiring time to prepare the jig.

### BRIEF DESCRIPTION OF THE DRAWINGS

FIG. 1 is a block diagram showing the structure of a major portion of semiconductor test apparatuses in accordance with first and second embodiments of the present invention.

FIG. 2 is a flowchart showing an example of the operation when adjusting skews between drivers 21a to 21n.

FIG. 3 is a diagram showing the structure of a driver pin block which is provided in a semiconductor test apparatus in accordance with the second embodiment of the present invention.

### DETAILED DESCRIPTION OF THE INVENTION

While embodiments of the present invention will be described and illustrated below, it should be understood that these are exemplary of the present invention and are not to be considered as limiting. Additions, omissions, substitutions, and other modifications can be made without departing from the gist or scope of the present invention. Accordingly, the present invention is not to be considered as being limited by the following description, and is only limited by the scope of the appended claims.

Hereinbelow, semiconductor test apparatuses in accordance with embodiments of the present invention will be explained in detail with reference to the attached drawings. In order to facilitate the understanding, the following description assumes an example in which a semiconductor device, i.e., a device under test, is a semiconductor memory and a semiconductor test apparatus is a memory tester which tests the semiconductor memory. In addition, although memory testers are provided with: driver pins at which drivers are provided; and I/O (Input/Output) pins at which drivers and comparators are provided, the following description explains the driver pins in detail, and the explanation relating to the I/O pins is omitted unless otherwise necessary.

### First Embodiment

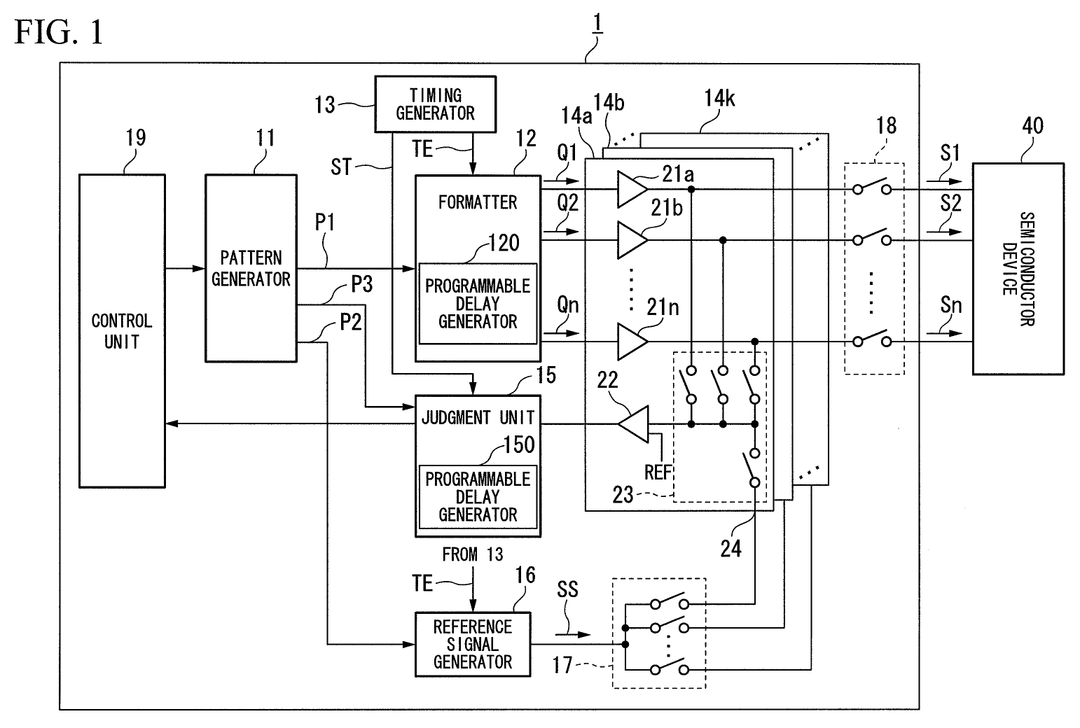

FIG. 1 is a block diagram showing the structure of a major portion of a semiconductor test apparatus in accordance with a first embodiment of the present invention. As shown in FIG. 1, a semiconductor test apparatus 1 of the present embodiment is provided with: a pattern generator 11; a formatter 12; a timing generator 13; driver pin blocks 14a to 14k; a judgment unit 15; a reference signal generator 16 (a reference signal generation unit); switch units 17 and 18; and a control unit 19. The semiconductor test apparatus 1 tests a semiconductor device 40 which is a device under test based on signals which are obtained by applying signals such as test signals S1 to Sn to the semiconductor device 40. It should be noted that the test signals S1 to Sn output from the driver pin block 14a are applied to, for example, address pins of the semiconductor device 40, and when data is read out from the semiconductor device 40 as a result of the application of the test signals S1 to Sn, the data is received by I/O pins (not shown) and then a pass or a fail of the semiconductor device 40 is judged.

Under the control of the control unit 19, the pattern generator 11 generates a test pattern used for producing test signals applied to the semiconductor device 40 and a test pattern used for adjusting the timings of signals output from drivers 21a to 21n (the details thereof will be explained later) provided in each of driver pin blocks 14a to 14k, and outputs these test patterns as a test pattern P1. In addition, under the control of the control unit 19, the pattern generator 11 generates and outputs a reference pattern P2 used for producing a reference signal SS which is used to adjust differences in the determination timings of a pass or a fail due to variations in characteristics between comparators for adjustment 22 (the details thereof will be explained later) provided in each of the driver pin blocks 14a to 14k. It should be noted that in the following description, the adjustment of the differences between the determination timings due to the variations in characteristics of the comparators for adjustment 22 may be simply referred to as “the timing adjustment of the comparators for adjustment 22”. The pattern generator 11 also generates and outputs expected values P3 respectively corresponding to the test pattern P1 and the reference pattern P2.

The formatter 12 receives the test pattern P1 output from the pattern generator 11, and generates signals Q1 to Qn, from which the test signals S1 to Sn are generated and the timings of which have been determined, based on a timing edge signal TE output from the timing generator 13 and the input test pattern P1. The formatter 12 includes programmable delay generators 120 such as a programmable delay line, and performs fine adjustment of the output timings of the signals Q1 to Qn under the control of the control unit 19. It should be noted that the programmable delay generators 120 are provided so as to correspond to the respective drivers 21a to 21n provided in each of the driver pin blocks 14a to 14k.

The timing generator 13 generates the timing edge signal TE which specifies the timings of the test signals S1 to Sn and the reference signal SS, and a strobe signal ST which specifies the timing when the judgment unit 15 judges a pass or a fail. It should be noted that the timing edge signal TE and the strobe signal ST generated by the timing generator 13 specify the timing of a test signal which is output to the semiconductor device 40 through the I/O pins (not shown). The timing edge signal TE and the strobe signal ST are also used for judging a pass or a fail of the semiconductor device 40 based on signals received through the I/O pins.

Each of the driver pin blocks 14a to 14k is provided with: a plurality of drivers 21a to 21n; a comparator for adjustment (hereinafter referred to as “adjustment comparator”) 22; a switch unit 23; and a reference signal input terminal 24, and generates from the signals Q1 to Qn the test signals S1 to Sn applied to the semiconductor device 40. The driver pin blocks 14a to 14k having such a structure make it possible to adjust the differences (driver skews) in timing between the test signals output from the drivers 21a to 21n without using a jig (a short-circuiting chip) which is required by conventional semiconductor test apparatuses. It should be noted that in the following description, the adjustment of the differences in timing between the test signals output from the drivers 21a to 21n may be simply referred to as “the timing adjustment of the drivers 21a to 21n″.

The drivers 21a to 21n respectively generates the test signals S1 to Sn based on the signals Q1 to Qn output from the formatter 12. The adjustment comparator 22 is connected to the output terminals of the drivers 21a to 21n through the switch unit 23. The adjustment comparator 22 is used for adjusting the timings of the drivers 21a to 21n. The switch unit 23 is provided with: a plurality of switches which connect and disconnect between the output terminals of the drivers 21a to 2 1n and the input terminal of the adjustment comparator 22; and a switch which connects and disconnects between the reference signal input terminal 24 and the input terminal of the adjustment comparator 22. The switch unit 23 connects any one of the drivers 21a to 21n and the reference signal input terminal 24 to the input terminal of the adjustment comparator 22.

It should be noted that the opening and closing of the plurality of switches provided in the switch unit 23 is controlled by the control unit 19. Switches such as an FET (Field Effect Transistor) switch and a diode bridge can be used as the switches provided in the switch unit 23. The reference signal input terminal 24 is an input terminal for inputting the reference signal SS generated by the reference signal generator 16 to each of the driver pin blocks. Although FIG. 1 shows only the internal structure of the driver pin block 14a, the internal structures of the other driver pin blocks 14b to 14k is the same as that of the driver pin block 14a.

The judgment unit 15 judges a pass or a fail of the semiconductor device 40 by comparing a signal output from the adjustment comparator 22 provided in each of the driver pin blocks 14a to 14k with the expected value P3 output from the pattern generator 11 at the timing specified by the strobe signal ST output from the timing generator 13. The judgment result of the judgment unit 15 is output to the control unit 19. The judgment unit 15 includes a programmable delay generator 150 such as a programmable delay line similar to the formatter 12, and performs fine adjustment of the judgment timing using the strobe signal ST under the control of the control unit 19.

The reference signal generator 16 receives the reference pattern P2 output from the pattern generator 11, and generates the reference signal SS, which is used for adjusting the timing of the adjustment comparator 22, based on the timing edge signal TE output from the timing generator 13 and the input reference pattern P2. The switch unit 17 is provided with a plurality of switches which connect and disconnect between the output terminal of the reference signal generator 16 and the reference signal input terminal 24 of each of the driver pin blocks 14a to 14k. The switch unit 17 performs switching as to whether or the reference signal SS is supplied to each of the driver pin blocks 14a to 14k. It should be noted that the opening and closing of the plurality of switches provided in the switch unit 17 is controlled by the control unit 19.

The switch unit 18 is provided with a plurality of switches which connect and disconnect between the drivers 21a to 2 in provided in each of the driver pin blocks 14a to 14k and the semiconductor device 40. The switch unit 18 performs switching as to whether or not the drivers 21a to 21n are electrically disconnected from the semiconductor device 40. It should be noted that the opening and closing of the plurality of switches provided in the switch unit 18 is controlled by the control unit 19. The adjustment of skews between the drivers 21a to 21n is performed with the switches provided in the switch unit 18 opened and the output terminals of the drivers 21a to 21n opened.

The control unit 19 controls the overall operation of the semiconductor test apparatus 1 by controlling the respective blocks provided in the semiconductor test apparatus 1. For example, when starting the test of the semiconductor device 40, the plurality of the switches provided in the switch unit 18 are closed, and the pattern generator 11 is controlled to generate the test pattern PI and the expected value P3. On the other hand, when adjusting the skews between the drivers 21a to 21n provided in each of the driver pin blocks 14a to 14k, the opening and closing of the switches provided in the switch unit 23 and the switch units 17 and 18 are controlled, the pattern generator 11 is controlled to generate the test pattern P1, the reference pattern P2, and the expected value P3, and the programmable delay generators 120 and 150 respectively provided in the formatter 12 and the judgment unit 15 are controlled based on the judgment result of the judgment unit 15. It should be noted that FIG. 1 shows only a control signal supplied to the pattern generator 11 from among control signals for controlling the respective blocks.

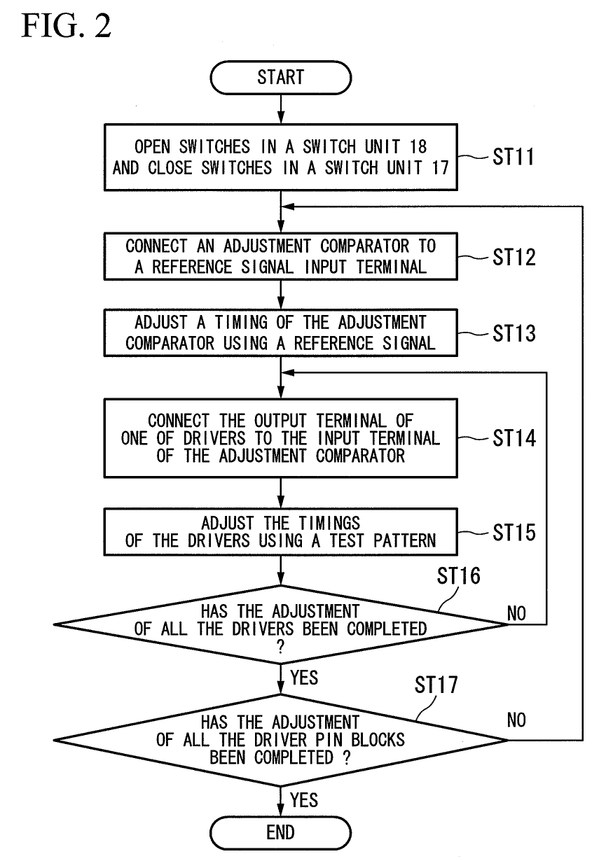

Next, the operation of the skew adjustment performed by the semiconductor test apparatus 1 will be explained. FIG. 2 is a flowchart showing an example of the operation of the adjustment of skews between the drivers 21a to 21n. It should be noted that the processes shown in FIG. 2 is started in response to a skew adjustment instruction from a user to the control unit 19. Once the processing is started, the control unit 19 makes all the switches provided in the switch unit 18 opened and makes all the switches provided in the switch unit 17 closed (step ST11). As a result, the output terminals of the drivers 21a to 21n are disconnected from the semiconductor device 40 and these output terminals are opened, and the output terminal of the reference signal generator 16 is electrically connected with the reference signal input terminal 24 provided in each of the driver pin blocks 14a to 14k.

Subsequently, the control unit 19 controls the switches provided in the switch unit 23 of the driver pin block 14a so as to connect the input terminal of the adjustment comparator 22 provided in the driver pin block 14a with the reference signal input terminal 24 (step ST12). Upon completion of the foregoing setting, the control unit 19 outputs a control signal for instructing the generation of the reference pattern P2 to the pattern generator 11 so as to adjust the timing of the adjustment comparator 22 (step ST13).

Specifically, when the control signal is output from the control unit 19, the pattern generator 11 generates the reference pattern P2 and the expected value P3 therefor based on the control signal. The generated reference pattern P2 is output to the reference signal generator 16, and the generated expected value P3 is output to the judgment unit 15. When the reference pattern P2 is input to the reference signal generator 16, the reference signal SS is generated from the reference pattern P2 and the timing edge signal TE output from the timing generator 13. The reference signal SS is input to the driver pin block 14a through the switch unit 17.

The reference signal SS which has been input to the driver pin block 14a is input to the input terminal of the adjustment comparator 22 through the switch unit 23. The reference signal SS is then compared with a predetermined reference voltage REF, and a signal indicating the comparison result is output from the adjustment comparator 22. The signal output from the adjustment comparator 22 is input to the judgment unit 15, and the input signal is compared with the expected value P3 output from the pattern generator 11 at the timing specified by the strobe signal ST output from the timing generator 13, thereby a pass or a fail of the semiconductor device 40 is judged.

The control unit 19 repeats the foregoing operations while varying the delay amount of the programmable delay generator 150 provided in the judgment unit 15, and the control unit 19 determines a turning point between a pass and a fail. The control unit 19 then sets the delay amount of the programmable delay generator to a delay amount at which the turning point has been determined. As a result, fine adjustment of the judgment timing of the strobe signal ST is performed, and thus the timing of the adjustment comparator 22 is adjusted.

Next, the control unit 19 controls the switches provided in the switch unit 23 of the driver pin block 14a so as to disconnect the adjustment comparator 22 provided in the driver pin block 14a from the reference signal input terminal 24 and to connect one of the output terminals of the drivers 21a to 21n (in this case the driver 21a) with the input terminal of the adjustment comparator 22 (step ST14). Subsequently, the control unit 19 outputs a control signal for instructing the generation of the test pattern P1 to the pattern generator 11, thereby adjusting the timing of the driver (in this case the driver 22a) connected to the adjustment comparator 22 (step ST15).

Specifically, when the control signal is output from the control unit 19, the pattern generator 11 generates the test pattern P1 and the expected value P3 therefor based on the control signal. The generated test pattern P1 is output to the formatter 12, and the generated expected value P3 is output to the judgment unit 15. When the test pattern P1 is input to the formatter 12, the signals Q1 to Qn whose timings have been determined are generated from the test pattern P1 and the timing edge signal TE output from the timing generator 13. The signals Q1 to Qn are respectively input to the drivers 21a to 21n provided in the driver pin block 14a. The drivers 21a to 21n respectively generate signals corresponding to the test signals S1 to Sn.

Among the signals generated by the drivers 21a to 21n, the signal generated by the driver 21a is input to the input terminal of the adjustment comparator 22 through the switch unit 23. The input signal is then compared with the predetermined reference voltage REF, and a signal indicating the comparison result is output from the adjustment comparator 22. The signal output from the adjustment comparator 22 is input to the judgment unit 15, and the input signal is compared with the expected value P3 output from the pattern generator 11 at the timing specified by the strobe signal ST output from the timing generator 13, thereby a pass or a fail of the semiconductor device 40 is judged.

The control unit 19 repeats the foregoing operations while varying the delay amount of the programmable delay generator provided for the driver 21a in the driver pin block 14a from among the programmable delay generators 120 provided in the formatter 12, and the control unit 19 determines a turning point between a pass and a fail. The control unit 19 the n sets the delay amount of the programmable delay generator to a delay amount for which the turning point has been determined, thereby adjusting the timing of the driver 21a.

Subsequently, the control unit 19 judges whether or not the timing adjustment has been completed for all the drivers 21a to 21n provided in the driver pin block 14a (step ST16). If the determination result is “NO”, the control unit 19 controls the switches provided in the switch unit 23 of the driver pin block 14a so as to connect the output terminal of another driver (e.g., the driver 21b) with the input terminal of the adjustment comparator 22 (step ST14), and adjusts the timing of the driver 21b (step ST15).

In contrast, if the determination result in the step ST16 is “YES”, the control unit 19 judges whether or not the timing adjustment has been completed for all the drivers provided in the driver pin blocks 14a to 14k (step ST17). If the determination result is “NO”, the control unit 19 control the switches provided in the switch unit 23 of a driver pin block (e.g., the driver pin block 14b) for which timing adjustment has not yet been completed so as to connect the input terminal of the adjustment comparator 22 of this driver pin block with the reference signal input terminal 24 (step ST12), and adjusts the timing of the adjustment comparator 22 (step ST13). Thereafter, the control unit 19 adjusts the timings of the drivers 21a to 21n provided in this driver pin block (steps ST14 and ST15). On the other hand, if the determination result in the step ST17 is “YES”, a series of operations is completed.

As explained above, the semiconductor test apparatus 1 in accordance with the present embodiment is provided with the driver pin blocks 14a to 14k, each including: the plurality of the drivers 21a to 21n which generate the test signals S1 to Sn; the adjustment comparator 22 which is used for timing adjustment and is provided for each of the drivers 21a to 21n; and the reference signal input terminal 24 to which the reference signal SS for adjusting the timing of the adjustment comparator 23 is input. Therefore, the timings of the drivers 21a to 21n can be adjusted without using a jig (a short-circuiting chip) which is required in conventional semiconductor test apparatuses. As a result, the operational convenience can be increased, and skew can be adjusted efficiently without requiring time to prepare the jig.

It should be noted that the foregoing embodiment has been explained with respect to an example in which the timing adjustment of the adjustment comparator 22 and the timing adjustment of the drivers 21a to 21n are performed for each of the driver pin blocks 14a to 14k. However, it is possible to configure the semiconductor test apparatus 1 such that the timing adjustment is performed for all the comparators for adjustment 22 respectively provided in the driver pin blocks 14a to 14k, and then the timing adjustment is performed one after another for each of the drivers 21a to 21n provided in the driver pin blocks 14a to 14k.

### Second Embodiment

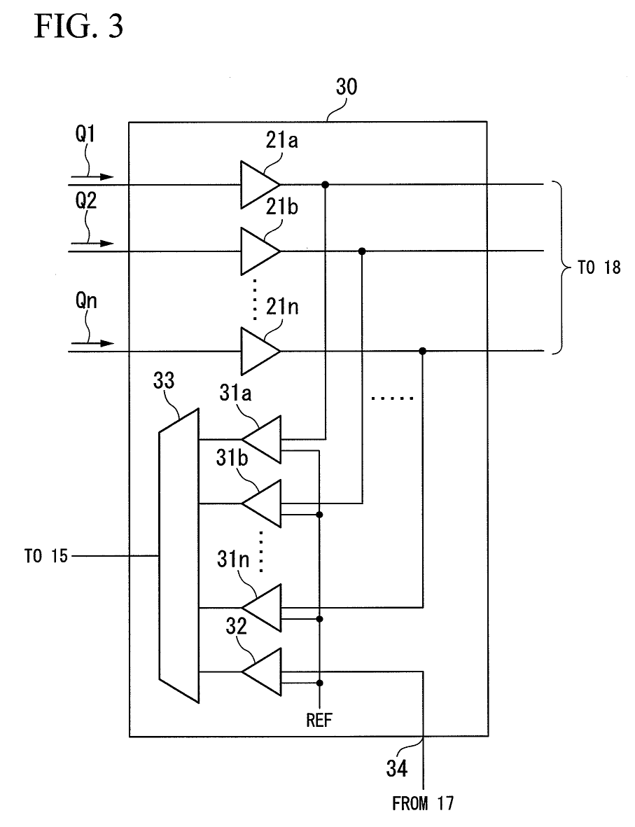

Next, a semiconductor test apparatus in accordance with the second embodiment of the present invention will be explained. The overall structure of the semiconductor test apparatus in accordance with the present embodiment is similar to that of the semiconductor test apparatus in accordance with the first embodiment shown in FIG. 1. However, they differ in that a driver pin block 30 shown in FIG. 3 is provided in place of the driver pin blocks 14a to 14k. FIG. 3 is a diagram showing the structure of a driver pin block provided in the semiconductor test apparatus in accordance with the second embodiment of the present invention.

As shown in FIG. 3, the driver pin block 30 is provided with: a plurality of drivers 21a to 21n; a plurality of comparators for adjustment 31a to 31n (first comparators); an adjustment comparator 32 (a second comparator); a selector 33 (a selection unit); and a reference signal input terminal 34. In other words, the driver pin block 30 shown in FIG. 3 includes the comparators for adjustment 31a to 31n; the adjustment comparator 32; and the selector 33 in place of the adjustment comparator 22 and the switch unit 23 which are provided in each of the driver pin blocks 14a to 14k shown in FIG. 1.

The comparators for adjustment 31a to 31n are provided so as to correspond to the drivers 21a to 21n, respectively, and the input terminals of the comparators for adjustment 31a to 31n are respectively connected to the output terminals of the drivers 21a to 21n. The comparators for adjustment 31a to 31n are provided so as to allow the individual adjustment of the timings of the drivers 21a to 21n. The adjustment comparator 32 is provided so as to allow the adjustment of the timings of the comparators for adjustment 31a to 31n.

Since the comparators for adjustment 31a to 31n and the adjustment comparator 32 are manufactured and integrated in accordance with the same manufacturing process, it is possible to deem that these comparators have almost the same characteristics. Therefore, by using the result obtained from the timing adjustment of the adjustment comparator 32 (i.e., the delay amount of the programmable delay generator 150 provided in the judgment unit 15) for the comparators for adjustment 31a to 31n, the timings of the comparators for adjustment 31a to 31n can be adjusted.

The selector 33 selects one of the outputs of the comparators for adjustment 31a to 31n and the output of the adjustment comparator 32 under the control of the control unit 19. The reference signal input terminal 34 is connected to the switch unit 17 in the same manner as the reference signal input terminal 24 shown in FIG. 1, and the reference signal SS output from the reference signal generator 16 is input to the driver pin block 30.

The adjustment of skew in the present embodiment is performed in accordance with processes similar to those of the flowchart shown in FIG. 2. However, the present embodiment differs from the first embodiment in that the control unit 19 of the first embodiment controls the switch unit 23 to switch drivers to be connected to the adjustment comparator 22, while in the present embodiment the selector 33 selects the outputs of the comparators for adjustment 31a to 31n and 32. The present embodiment also differs from the first embodiment in that the present embodiment adjusts the timing of the adjustment comparator 32 and then adjusts the timings of the comparators for adjustment 31a to 31n using the result of the timing adjustment of the adjustment comparator 32.

As explained above, the semiconductor test apparatus of the present embodiment is provided with the driver pin block 30 which includes: the plurality of drivers 21a to 21n which generate the test signals S1 to Sn; the adjustment comparators 31a to 31n which are respectively connected to the output terminals of the drivers 21a to 21n; the adjustment comparator 32 which is connected to the reference signal input terminal 34; the selector 33 which selects one of the outputs of the comparators for adjustment 31a to 31n and the adjustment comparator 32; and the reference signal input terminal 34 to which the reference signal SS is input. Therefore, in the same manner as the first embodiment, the timings of the drivers 21a to 21n can be adjusted without using a jig (a short-circuiting chip) which is required in conventional semiconductor test apparatuses. As a result, the operational convenience can be increased, and skew can be adjusted efficiently without requiring time to prepare the jig.

Although semiconductor test apparatuses in accordance with the embodiments of the present invention have been explained, the present invention is not limited to the foregoing embodiments, and various modifications can be made within the scope of the present invention. For example, although the foregoing embodiments explain examples in which the semiconductor test apparatuses are memory testers, the present invention can also be applied to not only logic testers which test semiconductor logic circuits but also semiconductor test apparatuses used for testing semiconductor devices such as a driver for an LCD (Liquid Crystal Display).

1. A semiconductor test apparatus which tests a semiconductor device based on a signal obtained by applying a test signal to the semiconductor device,
the semiconductor test apparatus comprising a driver pin block, the driver pin block including:
a plurality of drivers which generate the test signal;
at least one adjustment comparator which is connected to output terminals of the drivers and which is used for adjusting timings of the drivers; and
a reference signal input terminal to which a reference signal for adjusting a timing of the adjustment comparator is input.

2. The semiconductor test apparatus as recited in claim 1, further comprising:
a reference signal generation unit which generates the reference signal; and
a control unit which adjusts the timing of the adjustment comparator by controlling the reference signal generation unit to supply the reference signal to the driver pin block through the reference signal input terminal, and adjusts the timings of the drivers in accordance with a signal output from the adjustment comparator.

3. The semiconductor test apparatus as recited in claim 2, wherein the control unit adjusts the timings of the adjustment comparator and the drivers with the output terminals of the drivers opened.

4. The semiconductor test apparatus as recited in claim 1, wherein the driver pin block comprises a switch unit which connects one of the drivers and the reference signal input terminal to the adjustment comparator.

5. The semiconductor test apparatus as recited in claim 1, wherein the adjustment comparator comprises: a plurality of first comparators respectively connected to the output terminals of the drivers; and a second comparator connected to the reference signal input terminal, and the semiconductor test apparatus further comprises a selection unit which selects one of outputs of the first comparators and an output of the second comparator.

6. The semiconductor test apparatus as recited in claim 2, further comprising a judgment unit which judges a pass or a fail of the semiconductor device at a judgment timing based on an expected value and the signal output from the adjustment comparator,
wherein the control unit adjusts the timing of the adjustment comparator by determining a turning point between the pass and the fail based on a judgment result of the judgment unit while varying the judgment timing and setting the judgment timing to a timing for which the turning point has been determined.

7. The semiconductor test apparatus as recited in claim 2, further comprising a judgment unit which judges a pass or a fail of the semiconductor device based on an expected value and the signal output from the adjustment comparator,
wherein the control unit adjusts the timing of a driver by determining a turning point between the pass and the fail based on a judgment result of the judgment unit while varying a timing of a signal supplied to an input terminal of the driver and setting the timing of the signal supplied to the input terminal of the driver to a timing for which the turning point has been determined.

8. The semiconductor test apparatus as recited in claim 5, wherein the first comparators and the second comparator are manufactured and integrated by the same manufacturing process.

9. The semiconductor test apparatus as recited in claim 2, wherein the driver pin block comprises a switch unit which connects one of the drivers and the reference signal input terminal to the adjustment comparator.

10. The semiconductor test apparatus as recited in claim 3, wherein the driver pin block comprises a switch unit which connects one of the drivers and the reference signal input terminal to the adjustment comparator.

11. The semiconductor test apparatus as recited in claim 2, wherein the adjustment comparator comprises: a plurality of first comparators respectively connected to the output terminals of the drivers; and a second comparator connected to the reference signal input terminal, and the semiconductor test apparatus further comprises a selection unit which selects one of outputs of the first comparators and an output of the second comparator.

12. The semiconductor test apparatus as recited in claim 3, wherein the adjustment comparator comprises: a plurality of first comparators respectively connected to the output terminals of the drivers; and a second comparator connected to the reference signal input terminal, and the semiconductor test apparatus further comprises a selection unit which selects one of outputs of the first comparators and an output of the second comparator.

13. The semiconductor test apparatus as recited in claim 11, wherein the first comparators and the second comparator are manufactured and integrated by the same manufacturing process.

14. The semiconductor test apparatus as recited in claim 12, wherein the first comparators and the second comparator are manufactured and integrated by the same manufacturing process.
